(19) United States
(12) Patent Application Publication
(10) Pub. No.: US 2026/0318854 A1
(43) Pub. Date: Oct. 15, 2026

(54) METHOD FOR INSPECTING A SEMICONDUCTOR SAMPLE USING A SECONDARY-ION MASS SPECTROMETER WITH A FOCUSED ION BEAM, AND ANALYSIS DEVICE FOR THIS PURPOSE

(71) Applicant: Raith GmbH, Dortmund (DE)

(72) Inventors: Ulrich MANTZ, Schelklingen (DE); Markus MUELLER, Marl (DE); Alexander OST, Rollingen (LU); Martin RASCHE, Senden (DE)

(73) Assignee: Raith GmbH, Dortmund (DE)

(21) Appl. No.: 19/700,776

(22) Filed: Jun. 8, 2026

Related U.S. Application Data
(63) Continuation of application No. PCT/DE2024/101052, filed on Dec. 6, 2024.

(30) Foreign Application Priority Data
Dec. 8, 2023 (DE) 10 2023 134 499.4

(51) Int. Cl. G01N 23/22; H01J 49/00

(52) U.S. Cl. CPC G01N 23/22; H01J 49/0027; G01N 2223/33; G01N 2223/40; G01N 2223/6116

(57) ABSTRACT

A method for inspecting a semiconductor sample using a secondary-ion mass spectrometer (SIMS) with a material-removing focused ion beam. The semiconductor sample is positioned on a sample stage. An analysis scan is performed by irradiating a region-of-interest (ROI) in a semiconductor structure on the semiconductor sample with the ion beam. The secondary ions are generated in a mass spectrometer unit in order to generate an electronic image and/or other data set for characterizing the semiconductor structure in the region of the irradiated ROI. Navigation data is provided for the semiconductor sample with the semiconductor structure and the positioning marking. A preliminary scan is performed via a data-based navigation to a position marking and the region of the semiconductor sample is irradiated with the ion beam using a large scanning region. A SIMS analysis scan is performed using a scanning region which is reduced in comparison to the preliminary scan.

This nonprovisional application is a continuation of International Application No. PCT/DE2024/101052, which was filed on Dec. 6, 2024, and which claims priority to German Patent Application No. 10 2023 134 499.4, which was filed in Germany on Dec. 8, 2023, and which are both herein incorporated by reference.

### BACKGROUND OF THE INVENTION

### Field of the Invention

The invention relates to a method for inspecting a semiconductor sample using a secondary-ion mass spectrometer with a focused ion beam, as well as an analysis device for this purpose.

### Description of the Background Art

The manufacturing of multiple devices on a wafer scale is associated with multiple significant challenges, many of which have to do with the sensitive and precise nature, for example, of quantum devices and targeted technologies, These challenges include:
Uniformity and consistency: The devices require a precise control of materials and manufacturing processes. The achievement of uniformity and consistency in all devices on a wafer is crucial for their reliable operation. Deviations in terms of materials, dimensions, or processing steps may result in deviations from chip to chip.
Production tolerances: Devices often require a manufacturing in the nano-range, with extremely narrow tolerances. Achieving these tolerances across a large wafer may be technically challenging and require special manufacturing techniques.
Costs: Upscaling production on the wafer level may be expensive due to the need for special equipment and clean room facilities. Cost-efficient manufacturing methods for devices are a constant challenge.

The research and manufacturing of quantum devices is a promising area, in which academic groups as well as industrial enterprises are already active. A number of specific challenges for this new application are:
Error correction: Quantum error correction is a critical aspect of quantum computing. With multiple devices on a wafer, error correction becomes more complex, since errors in one device may have an effect on neighboring devices. The development of error correction strategies which are both effective and scalable is an important task.
Integration of components: Quantum devices may be made up of multiple components, for example, qubits, control electronics, and readout systems. The seamless integration of these components on a single wafer, while retaining their functionality, is challenging.
Testing and calibration: Every quantum device must be tested, calibrated, and characterized individually to ensure that it meets the performance specifications. This becomes more and more time- and resource-intensive the greater the number of devices on a wafer.
Noise: Quantum devices respond sensitively to noise quantities, including temperature fluctuations and electromagnetic radiation. Controlling and shielding these sources of interference is a challenge when multiple devices are arranged on a wafer in a densely packed manner.
Qubit crosstalk: In quantum computing, qubits (quantum bits) ideally do not interact with each other unless they are deliberately coupled. On a wafer having multiple qubits, it is enormously challenging to prevent unintentional interactions or crosstalk between adjacent qubits.
Scalability: As the number of quantum devices on a wafer increases, so does the complexity of the control and readout systems. It is an enormous technical challenge to scale quantum technologies in order to accommodate many devices on a single wafer without impairing performance.

Meeting these challenges requires a combination of advanced material science, manufacturing techniques, error correction strategies, and system integration approaches.

Secondary-ion mass spectrometry (SIMS) is a powerful analysis technique for inspecting semiconductor structures, in particular, during an error analysis accompanying the production process. SIMS delivers detailed pieces of information about the composition, structure, and distribution of elements and isotopes on the surface and, in this connection, also within semiconductor materials. The most important areas of application for SIMS in the semiconductor industry are:
Process control and quality assurance: SIMS is used for process control in semiconductor manufacturing. It contributes to ensuring the consistency and quality of thin-film deposition, ion implantation, etching, and other processes in that the elementary composition of the materials is analyzed in different process steps. This helps identify deviations or impurities, which could impair the performance of the end product.
Defect analysis: SIMS is extremely useful in identifying and characterizing defects in semiconductor materials and devices. It can detect tiny traces of impurities or foreign materials, which may cause defects in integrated circuits (ICs). This is crucial for improving yield and reliability.
Depth profiling: SIMS is particularly suitable for depth profiling, which enables semiconductor manufacturers to determine the distribution of dopants, impurities, and other materials in the different layers of semiconductor devices. This information is indispensable for optimizing the performance and reliability of the chips.
Elementary mapping: SIMS can create element maps which show the spatial distribution of the different elements on a semiconductor surface. This is valuable for identifying patterns, variations, and material interactions that are crucial for the process optimization and performance of the devices.
Material research and development: SIMS is used in research and development to develop new materials and methods for manufacturing semiconductors. Researchers can use SIMS to understand the behavior of materials at the atomic and molecular level, which is indispensable for improving semiconductor technologies and developing new ones.
Characterization of thin layers: SIMS us often used to characterize the composition of thin layers and multilayer structures in semiconductor elements. This is important for optimizing the properties of these materials for certain applications.
Monitoring of ion implantation: SIMS may be used to monitor the success and accuracy of ion implantation processes, which are indispensable for creating specific doping profiles in semiconductor materials.
Analysis of trace elements: Trace elements and impurities in semiconductor materials may be verified with the aid of SIMS. Even small amounts of impurities can impair the performance of devices, which is why a precise and highly sensitive detection is crucial.

The region on the semiconductor sample to be analyzed is usually first looked for during the use of SIMS, and the actual inspection is then carried out while remaining in this region.

The disadvantage of using SIMS in the inspection of thin-layered semiconductor topographies is that each irradiation operation reduces the semiconductor structure to a relevant degree in relation to the original structure thickness. While the electrical functionality is retained in conventional semiconductor structures having a usual layer thickness of >100 nm, despite structure loss caused by one or multiple analysis processes using SIMS, this is not the case in modern thin-layered structures with a thickness of 25 nm and less. During each SIMS analysis operation, a structure loss and primary ion implantation take pace in an irradiated region, which are so considerable that—depending on the raster density—the electrical functionality is no longer given after even a few passes, or a troubleshooting using the same wafer can no longer be continued.

Even if a functionality of the semiconductor structure is no longer necessary after the analysis, the material removal is disadvantageous, for example during an analysis for three-dimensional structural clarification, modern semiconductor structures having multiple planes become more and more important. In certain circumstances, it may no longer be possible to determine whether a surface defect was already present due to manufacturing or was induced later on by preliminary scans using the focused ion beam.

Further disadvantages of this procedure may be that modern, dense semiconductor structures may not be analyzed precisely enough, so that the probing of the desired target region requires manual intervention and therefore may not be able to be reproduced by machine, and a reliable data correlation with other data sources is not possible, for example with optical or electron-microscopic images.

### SUMMARY OF THE INVENTION

It is therefore an object of the present invention to improve a method for inspecting a semiconductor sample using a secondary-ion mass spectrometer (SIMS) with a focused ion beam (FIB) in such a way that the structure loss or the primary ion implantation on the semiconductor sample is reduced, so that a greater number of inspection passes for testing multiple ROIs on the same semiconductor sample is possible, the electrical functionality of the semiconductor structure preferably being retained, and largely automatic and easily reproducible analyses being made possible.

A fundamental idea of the invention is that the target region in the semiconductor structure which is of interest for the inspection (so-called region of interest, ROI) is approached in a targeted manner, using navigation data obtained in advance and relating to the semiconductor structure, and the focused ion beam is applied to the semiconductor structure only in the approached ROI.

When reference is made below to an “ion beam,” this may always refers to a “focused ion beam” (FIB), which is known as a means for surface analysis, emitted ions, usually gallium or helium, being used. The ion beam is focused on a point with the aid of electrostatic and magnetized lenses and passed over the surfaces row by row. Secondary electrons emerge from the surface, which are detected and make an imaging of the surface possible. However, a material removal of the structure to be analyzed is always associated therewith. This unavoidable material removal is moved, according to the invention, to regions situated outside the semiconductor structure to be analyzed.

In simplified terms, according to the invention, the sample stage is initially moved only with the aid of navigation data in such a way that the focused ion beam may initially be used in a region of the sample which does not have to be precisely analyzed. An existing or specifically added, easily apparent marking is irradiated there with the focused ion beam for the purpose of carrying out a correction using the setpoint position derived from the navigation data and the actual position ascertained while removing material. The marking may be a characteristic structural feature within the semiconductor structure to be analyzed, for example, an angle or a crossing point.

The inspection method presented here is particularly suitable for samples in semiconductor manufacturing (for example, CMOS, compound semiconductors, etc.).

Within the meaning of the present invention, the designation as “semiconductor” also includes structures made from materials which are not semiconductive in the physical/electrical sense, but which are applied to substrates of the same type, using the same types of manufacturing methods as in the case of semiconductor manufacturing, and with similar layer thickness and structure sizes.

However, the method also applies to other samples, for which precise navigation data are present, for example stone samples, which were inspected ahead of time, for example using an SEM or light microscope. The term “semiconductor sample” is used exclusively below in a more general way.

Within the meaning of the invention, “semiconductor samples” relate to a sequence of multiple dies or a single die on a substrate with regard to complete wafers containing multiple dies. The method also relates to the inspection of semiconductor structures independently of their size and arrangement. Only one wafer or another substrate is preferably introduced into the sample chamber.

If multiple semiconductor samples on multiple wafers or on other substrates separated from each other are introduced together into the sample chamber and inspected there, the inspection method of the invention may be carried out individually for each substrate multiple times.

At the end of the method, an electronic image comparable to an SEM image and/or another data set is to be obtained, which is suitable for characterizing the semiconductor structure in the region of the irradiated ROI. This may also include, for example, measurement results, by means of which contaminations with foreign atoms may be verified.

The image may be an image obtained from the secondary electron emissions, detectable by the human eye, which is comparable to a recording of a scanning electron microscope.

In particular, point spectra, line spectra, or image spectra may be considered as other data sets to be obtained. If point, line, or image spectra are recorded, a complete spectrum exists for each pixel. The data formats used for this purpose are usually proprietary formats of the manufacturer, and the volume of data is large. As an alternative, one may choose to record only scalar values, for example, the sum of a copper signal, for each pixel. An image with false color imaging in .bmp or .tif format may be obtained therefrom. The data volume is then significantly smaller, and a measure for the copper distribution may nevertheless be obtained in the aforementioned example.

While the spectra are usually recorded in 0D, 1D, 2D on the X, Y surface, i.e., as a point, line, or image spectrum, one may alternatively also place the ion beam on a point for a longer period of time. The beam “digs” deep into the sample due to the sputter effect. A depth profile is then obtained in direction Z for this X, Y point.

A material removal of this type with the goal of obtaining a depth profile may be achieved, according to the invention, not only at a single point, but also by tracing a path in the plane, in that at least one upper semiconductor layer is partially removed by carrying out the analysis scan multiple times using the same navigation data, and an inspection is made possible in a further semiconductor layer situated below the partially removed semiconductor layer.

Correspondingly, “another data set” comprises, within the meaning of the present invention, point spectra, line spectra, and/or image spectra, and/or images, which show the distribution of an individual element, and/or a depth profile, which reflects the distribution of an element in the Z direction.

Navigation for the semiconductor sample may be obtained from:
CAD data, such as GDS II files;
position lists, such as KLARF files for indicated defects of the semiconductor structure detected ahead of time; or
other image data, which have been recorded ahead of time using analysis methods which do not destroy the sample, for example light microscopy, and which are suitable for the orientation and precise localization of the ROI on the sample.

Within the meaning of the present invention, “data-based navigation” thus means that reproducible data are obtained, which relate to geometric features of the semiconductor structure on the semiconductor sample before the region of interest is approached and the ion beam directed onto any location on the semiconductor structure is switched on.

The selective approach of the target region is made possible in that the semiconductor sample having the semiconductor structure to be inspected is placed on a highly precise, movable sample stage, such as, in particular, a so-called laser interferometer stage. In addition, the invention provides for equipping the semiconductor sample with one or multiple positioning markings formed separately on the substrate outside the semiconductor structure to be inspected, or selecting characteristic geometric points within the semiconductor structure, at which a multiple irradiation with the ion beam is possible.

Within the meaning of the present invention, “positioning markings” are thus all reliably locatable points on the substrate of the semiconductor sample, which are formed in addition to the semiconductor structure or which are selected within the semiconductor structure, and for which a multiple irradiation is possible without disadvantages.

If there are more than two positioning markings, they are arranged in a distributed manner in such a way that they are not all situated on a straight line and are thus suitable as reference points in a 2D coordinate system.

It is also possible that dedicated markings outside the semiconductor structure are not used as positioning markings, but rather characteristic structures within the semiconductor structure or, for example, the lower left corner of a chip which is repeated multiple times on a wafer are selected for this purpose.

At the beginning of the analysis process, the region on the semiconductor sample containing at least one positioning marking is positioned under the ion beam on the basis of a setpoint value. The setpoint value is formed from the navigation data used for manufacturing the semiconductor sample and a fixed, known position on the sample stage.

An analysis of the region of the semiconductor probe having at least one positioning marking is then carried out in a first preliminary scan. This preliminary scan may be carried out by means of known SIMS or SE detection methods. The sample-internal coordinate system may be brought into alignment with the coordinate system of the sample stage by ascertaining the difference between the theoretical setpoint position of the positioning marking and the true actual position. By repeating the step for further positioning makings, errors in the positioning of the semiconductor sample may be detected not only in the X/Y plane of the sample stage, but also a rotation of the semiconductor sample relative to the sample stage and an error in the zoom factor, which occurs, for example, due to a deviating distance between the sample surface and the radiation source.

After the alignment, the sample stage is moved relative to the ion beam source positioned in a stationary manner and using the distances known from the navigation data into the sample stage plane for the purpose of precisely approaching the ROI to be inspected in the semiconductor structure. Only then is a SIMS analysis of the ROI carried out by means of an ion irradiation of the ROI.

The combination of CAD/blank sample navigation and SIMS offers multiple significant advantages, especially in relation to the precision, efficiency, and accuracy of the sample analysis. Specifically, these are:
Greater precision: The data-based navigation facilitates a precise and accurate sample positioning. It ensures that the SIMS apparatus precisely targets the location which is of interest on the sample surface or within a complex structure. This precision is crucial for the analysis of certain features, layers, or structures in semiconductor devices or other materials.
Efficient data capture: The data-based navigation streamlines the data capture process. Due to the precise specification of the regions of interest or features, for example in a CAD model, the SIMS apparatus may automatically scan and analyze these specific regions, by which means time-consuming manual adaptations are omitted.
Minimized sample damage: During the SIMS analysis, the primary ion beam may cause sputtering and thus damage to the sample surface as well as unwanted implantation of the primary ions. The data-based navigation minimizes this damage by ensuring that the ion beam scans only the regions of the semiconductor sample provided and that the integrity of the neighboring regions is preserved. In particular, it is ensured that the ROI itself does not undergo any preliminary damage due orientation scans which are otherwise necessary.
Handling of complex geometries: CAD models may precisely represent complex and 3D structures. This is particularly valuable in semiconductor manufacturing, where modern chips have complicated architectures. The data-based navigation enables SIMS to analyze specific layers, trenches, and vias within these complex structures.
Improved reproducibility: The data-based navigation facilitates consistent and reproducible analyses. Researchers and developers can store data-based navigation plans for future analyses and reuse them or exchange them with colleagues to ensure a consistent data capture and comparability.
Data correlation: The data-based navigation makes it easier to correlate SIMS data with other data sources, such as optical or electron-microscopic images. By matching the SIMS data with the CAD model, researchers can precisely correlate the SIMS results with the specific features of other imaging methods.

In summary, it may be said that the data-based navigation for SIMS significantly improves the possibilities and efficiency of the technology. It is particularly valuable in sectors such as semiconductor manufacturing, where the precise analysis of complex structures is indispensable for quality control and research and development. By integrating CAD models into SIMS instruments, researchers and developers can achieve a higher degree of accuracy, reproducibility, and productivity in their analysis processes.

Once the starting position for the analysis scan has been reached, the analysis scan may be carried out:
at a stationary position (spot mode), and/or
as an X/Y scan (raster scan mode), and/or
along a path established in advance from navigation data or a route, which may also be a polygonal chain (shape mode).

The above modes of the analysis scan may be carried out multiple times consecutively to perform an inspection in the depth of the sample (Z direction) with the aid of the sputter effect. In simplified terms, the inspection method in this example provides for digging into the depth of the semiconductor structure with the aid of the ion beam. For this purpose, upper layers must be partially removed, for which purpose the ion beam is varied in its intensity and/or irradiation duration per unit area in such a way that it has an heightened effect on the sample to the degree necessary for the pure SIMS analysis.

The sample inspection designated above as shape mode is of particular interest along a section of the semiconductor structure. In the case of known CAD data as navigation data and the possibility of highly precise positioning of the ion beam, a section of an etched trench, for example having a curve, or trenches having a certain design width, may be irradiated. This may be done for repeating substructures of the semiconductor structure, so that a statistical distribution or a distribution over the entire wafer or the substrate of the semiconductor sample is obtained. The distribution then provides information on the size of a process window.

The probe size should be smaller than the structure to be inspected, for example a trench width. In the case of very thin layers formed, for example, by impurities, the signal-to-noise ratio is also increased by the analysis scan, since a great deal more material is available for the analysis than in a pure single-point analysis.

The positioning means and the diameter of the ion beam are preferably matched to each other in such a way that a resolution of better than 20 nm is obtained during analysis scans of trenches.

One advantageous variant of the inspection method provides that a semiconductor sample is used, which has at least three positioning markings on the same substrate as the semiconductor structure to be analyzed, which are arranged so as to be offset therefrom and are not all arranged on the same straight line. A precise calibration of a reference point in a two-dimensional plane is thus possible.

It may furthermore be advantageous if correction data for a position correction in the reference system of the sample stage and/or for a height position of the semiconductor sample on the sample stage relative to a primary ion column emitting the focused ion beam and/or a rotation error of the semiconductor sample in relation to the stationary housing having the primary ion column are ascertained from the preliminary scan of the at least three positioning markings, and the alignment is carried out on the basis of these correction data. The later structural clarification is made even more precise thereby.

A structure loss in the region of the positioning marking is effectuated by the alignment, using the SIMS, due to each irradiation operation. To compensate therefore or to mitigate it, different measures are possible.

For example, the positioning markings may be preferably formed in a thickness that is significantly greater than the layer thickness of the semiconductor structures to be clarified in layer analysis scans and which are, in particular, 2 times to 4 times the thickness of the semiconductor structure. A certain material removal is thus possible due to multiple raster scans.

It is also possible to provide more than one set of positioning markings on the semiconductor sample and to carry out the alignment with a second set after a first set has been impaired by preceding preliminary scans for alignment operations.

It is particularly advantageous if the raster speed for the preliminary scan carried out for the purpose of the alignment is increased over that of the analysis scan to follow later on, for example, two-fold to four-fold higher. This means that the pixel dwell time is shorter and the irradiation intensity decreases, which results in less destruction of the positioning markings. The increased image noise due to the higher raster speed is not harmful, because the positioning markings are large in relation to the size of the ROI and are geometrically designed, for example as a cross, in such a way that their center of gravity to be used as the coordinate system origin or coordinate system reference point or their center may not always be reliably detected.

In this connection, an example of the inspection method of the invention provides that certain size relationships are selected, and the positioning markings are designed to be large in comparison to the smallest structures to be resolved, namely, in particular, twice to 4 times the size of the planar extension of the ROI, the planar extension of the ROI being at least twice the size of the focused ion beam.

If the size of the focused ion beam (beam size/spot size) is 5 nm, the physical limit for the lateral resolution for the SIMS is approximately 10 nm, due to the lateral extension of the “collision cascade,” which describes the surface area from which secondary ions are emitted from the sample. Depending on the signal-to-noise ratio in the SIMS image, a lateral resolution of <20 nm may be routinely expected. The positioning markings are thereby made robust with respect to the unwanted sputtering during the preliminary scans.

An analysis device suitable for carrying out the inspection method is also provided.

It initially comprises a secondary-ion mass spectrometer, comprising a primary ion column, which contains a primary ion source and accelerates ions and applies them to the semiconductor sample as a focused ion beam; a high-vacuum sample chamber, in which the semiconductor sample and an extraction unit for secondary ions are arranged; as well as a mass spectrometer unit having a detector.

A mass analyzer is inserted into the mass spectrometer unit, which separates the secondary ions according to their mass/charge ratio.

The analysis device also comprises a sample stage, which is movable laterally at least in two surface coordinates, the sample stage plane being oriented normal to the focused ion beam. The sample stage has, in particular, a drive system to carry out a movement of the sample stage relative to the stationary sample chamber. For this purpose, spindles may be provided which are drive by DC motors or step motors.

The sample stage also comprises a feedback measurement system to establish the position of the sample stage within the sample chamber and possibly its displacement speed. An encoder may be connected to the spindle as the feedback measurement system, or encoders on glass measuring rods may be provided, which are positioned apart from the spindle.

A laser interferometer is particularly preferably used to achieve the greatest possible accuracy of the movement monitoring. Due to its local resolution in the sub-nanometer range, this also permits the successful approach to structures on chips which are repetitive in the range of several nanometers, for example, memory structures. The inspection of critical points in repetitive structures requires a local precision which is significantly better than half the repetition distance (pitch) of the structure.

A shift piezo actuator is additively used in the drive devices of both axes. Unlike the main drives, for example DC motors, the shift piezo actuators may continuously shift the sample stage without jolts. Due to the vary small displacement paths possible by the use of the shift piezo actuators, the use of a laser interferometer as the feedback measurement system is necessary in this example to fully utilize the possible precision in the nanometer range.

Finally, the analysis device also comprises a stage control unit to control the drives of the sample stage.

The carrying out of an analysis is described below, in which an analysis device is used, which has a stage control unit for the sample stage and a control PC for the secondary-ion mass spectrometer, as well as an ion column, in which the ion beam is deflected via electrostatic or electromagnetic fields, for which purpose a further control unit is provided.

If separate control units are provided for the sample stage, for the control of the ion beam by means of deflection, and for the secondary-ion mass spectrometer, the invention provides for a data link between the control units to coordinate the emission of the ion beam with the movement of the stage.

All control units for the ion beam, the sample stage, and the SIMS are monitored and controlled by a global control unit. The aforementioned control units may be designed to be physically separated or be formed by integrated modules within the global control unit.

In a first step, the ion source is started so that a stable ion beam is emitted. An alignment of the column is also carried out, so that the beam may strike the sample in the center through the beam aperture having the smallest possible diameter, depending on the diameter of the beam aperture, and a round shape. This procedure is carried out on a “dummy” sample or on a corner of the actual sample so that damage to the ROIs due to sputtering or ion implantation may not take place.

Once the preparations described above have been completed, a first target run of the sample stage may be carried out, for example to approach the region of one of the positioning markings on the semiconductor sample. For this purpose, a travel command with an X/Y target coordinate comes from the control PC for the stage control unit. It initially calculates a travel profile, i.e., X/Y setpoint values, from the starting point in time to the arrival, the profile typically containing acceleration and braking operations.

After the profile has been created, the travel is carried out, the stage control unit permanently controlling the following actions or performing inspections, for example at a frequency of 10 kHz: it sends control variables to the actuators, such as voltages for the DC motors of the drive system; it measures the instantaneous actual position by means of a laser interferometer; and it carries out a setpoint/actual comparison of the position and corrects the control variables of the actuators accordingly.

The stage control unit determines the reaching of the target position once the actual position is in a preselected tolerance field, the so-called error band. This is typical set to twice the spot size of the ion beam. For example, if the spot size is 5 nm, the size of the error band is set to 10 nm.

The stage control unit then switches off the actuators and sends a message to the control PC indicating that the target position was successfully approached.

In a preferred analysis device for carrying out the inspection method according to the invention, the following typical dimensions are given:
edge length of a semiconductor sample to be inspected: 100 mm;
Removal of position markings: 1 to 100 mm;
Travel distance during a target movement, e.g., from die to die: 5 mm;
Number of setpoint X/Y values to be precalculated for creating a travel profile along the travel path: approx. 50,000;
Travel speed: 2 mm/s (DC motors with spindles), up to 20 mm/s (piezo linear drives);
Error band for target arrival: 10 nm.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1. shows a schematic representation of an analysis device for inspecting a semiconductor sample;

FIG. 2 shows the path of a primary ion beam on a semiconductor sample in a schematic perspective view; and

FIGS. 3A and 3B each show a semiconductor sample on a sample stage from above.

### DETAILED DESCRIPTION

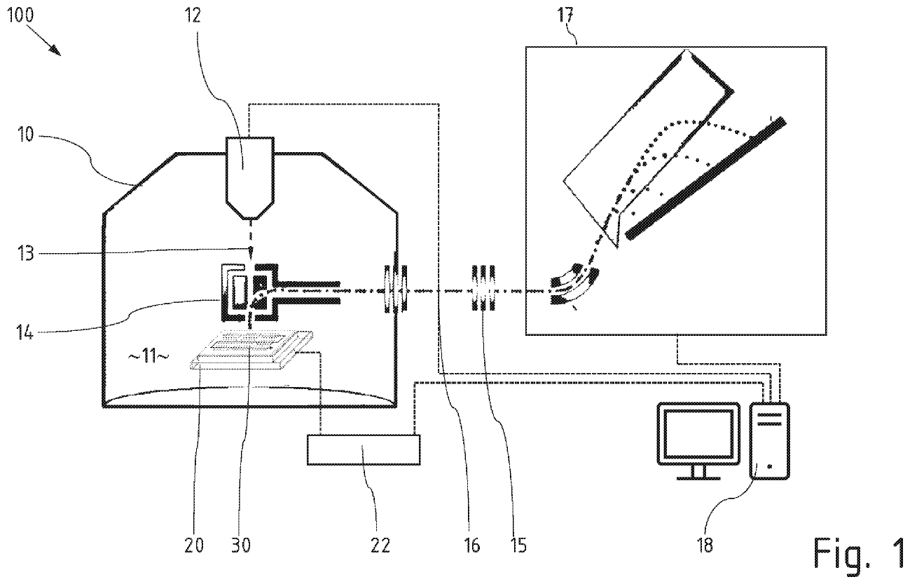

An analysis device 100 for inspecting a semiconductor sample is illustrated in FIG. 1. It largely corresponds to the known layout of a secondary-electron mass spectrometer, only the choice of a sample stage 20 being specifically adapted for carrying out the inspection method according to the invention.

A high-vacuum sample chamber 11 is formed in a housing 10, which may be closed pressure-tight and air-tight. Sample stage 20 is arranged therein. It comprises a base 21, which is fixedly connected to housing 10, and actual sample stage 20, on which a semiconductor sample 30 may be fastened, and which is movable with respect to the base at least two-dimensionally, generally in a Cartesian coordinate system. High-vacuum sample chamber 11 may be evacuated, so that a high vacuum may be applied. A primary ion source 12 is arranged in a vertically oriented column on the upper side of housing 20. Ion beam 13 emitted from there is oriented normal to sample stage 20.

An extraction unit 14 is arranged between primary ion source 12 and sample stage 20, which is used to capture, focus, and laterally discharge the secondary ions released from a semiconductor sample placed on sample stage 20. Secondary ion beam 16, which is formed in this way and deflected to the side, is focused by transfer lenses 15 and conducted to a mass spectrometer unit 17, where the secondary ions are separated according to their mass/charge ratio and guided to a detector.

The moving part of sample stage 20 is moved relative to the base by a stage control unit 22. Stage control unit 22 is connected to a control PC 18, by means of which primary ion source 12 is also controlled and on which the signals generated in the detector of mass spectrometer unit 17 are visualized.

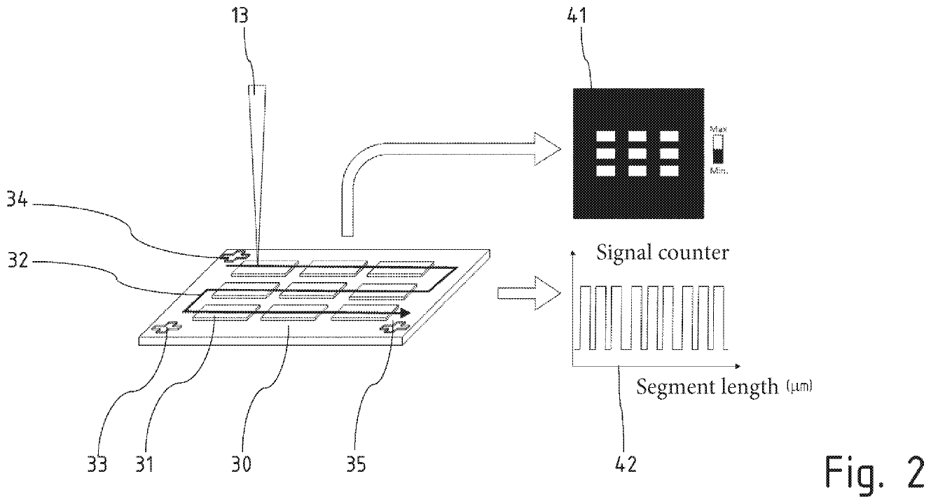

FIG. 2 shows a schematic, perspective view of a semiconductor sample 30, which is placed on the sample stage. it comprises multiple semiconductor structures to be inspected, which each form a region of interest (ROI) 31, and a total of three positioning markings 33, 34, 35 in two edge strips. Due to the movement of the sample stage, semiconductor sample 30 may be moved relative to vertically oriented primary ion beam 13, which is arranged in a stationary manner, on the basis of a movement path 32 predefined by the control unit of the sample stage. A line scan 42 may be carried out thereby, or an image 41 of semiconductor sample 30, or individual ROIs 31 thereon, may be generated. In addition, the regions having cross-shaped positioning markings 33, 34, 35 may be approached in a targeted manner.

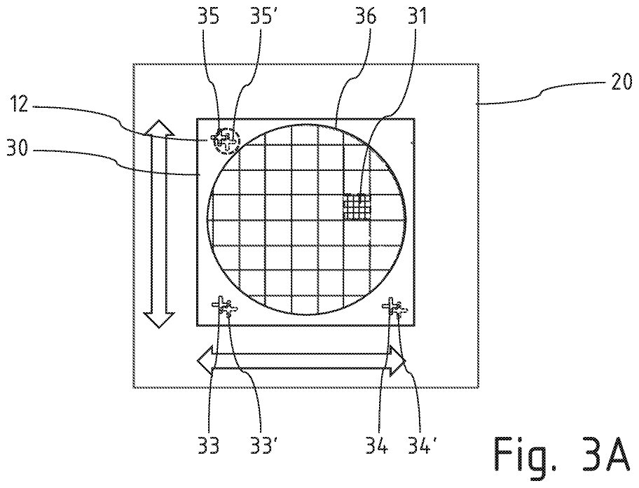

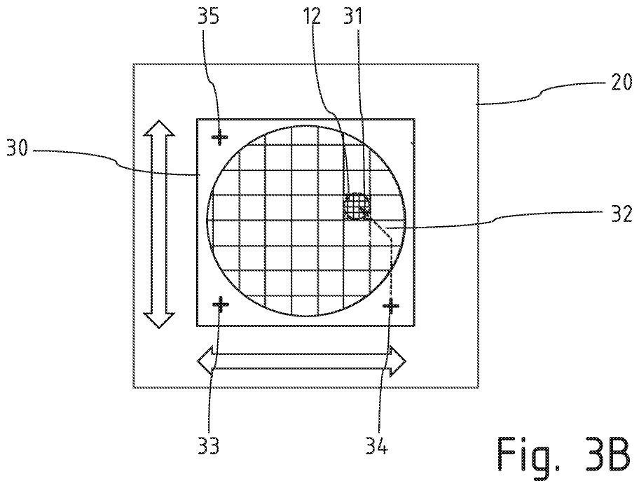

Semiconductor sample 30 fastened to sample stage 20 is shown from above in FIG. 3A. As indicated by the block arrows, sample stage 20 may be moved in the X and Y directions. At the start of the inspection method, sample stage 20 is positioned in such a way that the ion beam is situated over a positioning marking 35. A setpoint position 35′ for positioning marking 35 is derived from the production data of semiconductor sample 30. In FIG. 3A, setpoint position 35′ is identified by the dashed crosses. Due to the manual placement of semiconductor sample 30 on sample stage 20, a deviation between theoretical setpoint position 35′ ascertained from CAD data of semiconductor sample 30 and the actual position may already be expected. Primary ion beam 13 is therefore switched on at setpoint position 35′ to carry out an imaging preliminary scan, which is illustrated by the dashed circle. Positioning marking 35 is apparent in the edge region of the capture region around setpoint position 35′.

The preliminary scan is repeated by approaching setpoint positions 33′, 34′ for positioning markings 33, 34 to also detect possible rotation and zoom errors. With the aid of the deviations determined in the preliminary scans, the coordinate system derived from the CAD data of semiconductor sample 30 and the coordinate system actually given on the sample stage are brought into alignment so that all setpoint positions match the actual positions, as shown in FIG. 3B.

A movement path 32 may be generated from the last positioning marking 34 approached for a preliminary scan with the aid of the control until to place primary ion beam 13 exactly on an ROI 31 in order to carry out an analysis scan there.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for inspecting a semiconductor sample using a secondary-ion mass spectrometer (SIMS) with a material-removing, focused ion beam, the method comprising:
positioning the semiconductor sample on a sample stage;
performing an analysis scan by irradiating at least one region of interest in at least one semiconductor structure on the semiconductor sample with the ion beam for releasing secondary ions from the semiconductor structure;
registering the secondary ions in a mass spectrometer unit to generate an electronic image and/or another data set for characterizing the semiconductor structure in the region of the irradiated region of interest;
using a semiconductor sample, which has the semiconductor structure to be analyzed and at least one positioning marking on the same substrate;
using a sample stage, which is movable relative to the ion beam in at least two dimensions;
providing navigation data for the semiconductor sample having the semiconductor structure and the positioning marking;
performing a preliminary scan via data-based navigation to a position of a positioning marking derived from the navigation data and irradiating the region of the semiconductor sample with the ion beam using a large scanning region;
aligning an internal coordinate system for the sample stage by comparing the position of the positioning marking derived from the navigation data on the sample stage with the position of the positioning marking ascertained by the preliminary scan;
positioning the ion beam over the region of interest to be analyzed via data-based navigation of the sample stage and/or lateral deflection of the ion beam, the travel path of the sample stage leading to a position and/or an absolute value of the lateral deflection of the ion beam being calculated from the navigation data of the semiconductor sample; and
performing a SIMS analysis scan to generate the electronic image and/or the other data set by irradiating the semiconductor structure with the ion beam, using a scanning region which is reduced in comparison to the preliminary scan;
wherein the focused ion beam is guided over the semiconductor sample along a path defined ahead of time from navigation data or a route which may also be a polygonal chain, and the navigation data being reproducible data relating to geometric features of the semiconductor structure on the semiconductor sample, which are predefined by CAD data for manufacturing the semiconductor structure; and/or
wherein the focused ion beam carrying out an X/Y scan or raster scan mode for an elementary mapping, which shows the spatial distribution of the different elements on a semiconductor surface, is based on position lists for indicating defects of the semiconductor structure detected ahead of time.

2. The inspection method according to claim 1, wherein a semiconductor sample is used, which has at least three positioning markings on a same substrate as the semiconductor structure to be analyzed, which are arranged so as to be offset therefrom and are not all arranged on the same straight line.

3. The inspection method according to claim 2, wherein correction data for a position correction in the reference system of the sample stage and/or for a height position of the semiconductor sample on the sample stage relative to a primary ion column emitting the focused ion beam and/or a rotation error of the semiconductor sample in relation to the stationary housing having the primary ion column are ascertained from the preliminary scan of at least three positioning markings, and wherein the alignment is carried out on the basis of these correction data.

4. The inspection method according to claim 2, wherein more than one set of at least three positioning markings is provided on the semiconductor sample.

5. The inspection method according to claim 1, wherein the positioning markings are arranged so as to be offset from the semiconductor structure on the semiconductor sample.

6. The inspection method according to claim 1, wherein the positioning markings are formed in a thickness, which is greater than the layer thickness of the region of interest in the semiconductor structure to be clarified in later analysis scans.

7. The inspection method according to claim 1, wherein a raster speed at which the focused ion beam is passed over the surface in a preliminary scan for the purpose of the alignment is increased compared to a raster speed in the analysis scan following later on.

8. The inspection method according to claim 7, wherein the raster speed during the preliminary scan is increased to twice to four times the raster speed during the analysis scan.

9. The inspection method according to claim 1, wherein the planar extension of the positioning markings in the plane of the sample stage is in each case large in comparison to the size of the region of interest.

10. The inspection method according to claim 9, wherein the planar extension of the positioning markings is twice to four times the planar extension of the region of interest, the planar extension of the region of interest being at least twice the size of the focused ion beam.

11. The inspection method according to claim 1, wherein at least one upper semiconductor layer is partially removed by carrying out the analysis scan multiple times using the same navigation data, and an inspection is made possible in a further semiconductor layer situated under the partially removed semiconductor layer.
